(19) United States
(12) Patent Application Publication
(10) Pub. No.: US 2014/0175427 A1
(43) Pub. Date: Jun. 26, 2014

(54) THIN FILM TRANSISTOR

(71) Applicant: HON HAI PRECISION INDUSTRY CO., LTD., New Taipei (TW)

(72) Inventor: JIAN-SHIHN TSANG, Tu-Cheng (TW)

(73) Assignee: HON HAI PRECISION INDUSTRY CO., LTD., New Taipei (TW)

(21) Appl. No.: 14/035,964

(22) Filed: Sep. 25, 2013

(30) Foreign Application Priority Data
Dec. 25, 2012 (TW) 101149889

(51) Int. Cl. H01L 29/786

(52) U.S. Cl. CPC H01L 29/7869
USPC 257/43

(57) ABSTRACT

A thin film transistor includes a substrate and a channel layer formed on an upper surface of the substrate. A source electrode and a drain electrode are formed on an upper surface of the channel layer and located at two opposite ends of the upper surface of the channel layer. A gate insulating layer is located in a middle portion of the upper surface of the channel layer. A gate electrode is located on an upper surface of the gate insulating layer. The thin film transistor further includes a first organic air block layer. The first organic air block layer is formed between the substrate and the channel layer.

### BACKGROUND

1. Technical Field

The disclosure generally relates to a thin film transistor.

2. Description of Related Art

Nowadays, thin film transistors have been widely used in display devices to make the display devices become thinner and smaller. A typical thin film transistor includes a channel layer, a gate electrode, a source electrode and a drain electrode formed on the channel layer. The thin film transistor is turned on or turned off by controlling a voltage applied to the gate electrode.

Thin film transistors made of indium gallium zinc oxide (IGZO) material have been widely used in liquid crystal display panels, especially in liquid crystal display panels with a high resolution and a large size. Since IGZO films are easy to be affected by temperature, oxygen content, steam or illumination in outer environment, a protecting layer made of inorganic oxides or inorganic nitrides, such as SiO₂, Al₂O₃, SiON or SiOx, are formed on the IGZO films. However, the protecting layer made of inorganic oxides or inorganic nitrides is generally formed by plasma-enhanced chemical vapor deposition (PECVD) or by sputtering. In process, the IGZO films are easy to be damaged by plasma and a leakage current in the thin film transistor is increased. In addition, parameters such as threshold voltage, current on-off ratio, sub-threshold of the thin film transistor are also affected.

What is needed, therefore, is a thin film transistor to overcome the above described disadvantages.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a cross sectional view of a thin film transistor in accordance with a first embodiment of the present disclosure.

FIG. 2 is a cross sectional view of a thin film transistor in accordance with a second embodiment of the present disclosure.

FIG. 3 is a cross sectional view of a thin film transistor in accordance with a third embodiment of the present disclosure.

FIG. 4 is a cross sectional view of a thin film transistor in accordance with a fourth embodiment of the present disclosure.

FIG. 5 is a cross sectional view of a thin film transistor in accordance with a fifth embodiment of the present disclosure.

FIG. 6 is a cross sectional view of a thin film transistor in accordance with a sixth embodiment of the present disclosure.

### DETAILED DESCRIPTION

Embodiments of thin film transistors will now be described in detail below and with reference to the drawings.

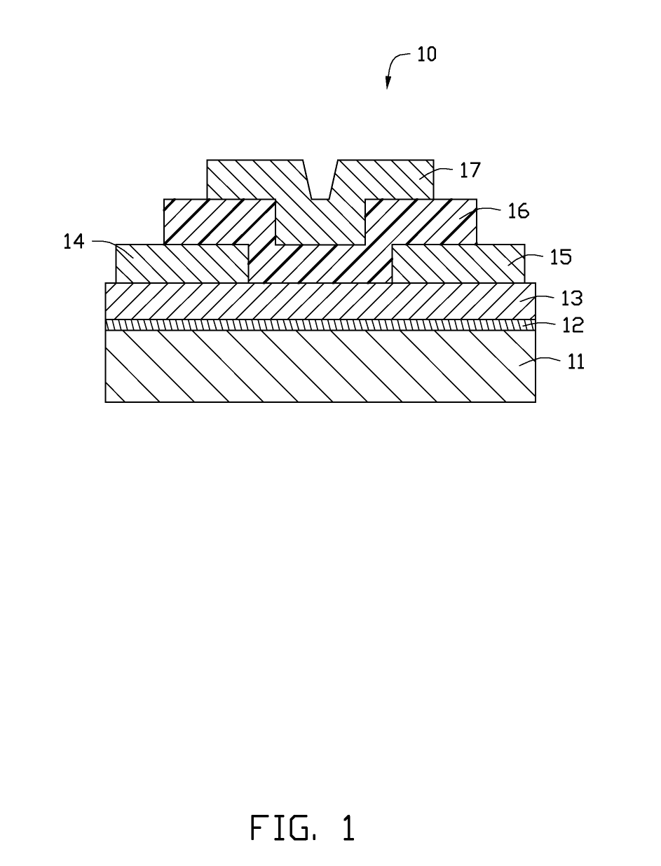

Referring to FIG. 1, a thin film transistor 10 in accordance with a first embodiment of the present disclosure is provided. The thin film transistor 10 includes a substrate 11, an organic air block layer 12, a channel layer 13, a source electrode 14, a drain electrode 15, a gate insulating layer 16 and a gate electrode 17.

The substrate 11 is configured to support the organic air block layer 12. The substrate 11 is made of a material selected from glass, quartz, silicon, polycarbonate, polymethyl methacrylate or metallic foil.

The organic air block layer 12 is formed on an upper surface of the substrate 11. Preferably, the organic air block layer 12 is made of hydrophobe, which includes at least one element of Si, N, H, O and C. In this embodiment, the organic air block layer 12 is made of a material selected from Hexamethyldisiloxane (C₆H₁₈OSi₂), Hexamethyldisilazane (C₆H₁₈NHSi₂), Polymethyl Methacrylate (PMMA), Epoxy, Polycarbonate (PC) and Plastic. A refractive index of the organic air block layer 12 is not less than 1.2 to avoid optical properties of the thin film transistor 10 being affected. The organic air block layer 12 can be formed on the substrate 11 by Chemical Vapor Deposition (CVD) or by Solution Processes, such as spray, spin coating, dispensing, ink jet.

The channel layer 13 is formed on an upper surface of the organic air block layer 12. The channel layer 13 is made of semiconductor oxides. Preferably, the channel layer 13 is made of metallic semiconductor oxides, which includes at least one of In, Ga, Zn, Sn, Al, Pb, Mo, Mn, Mg, Ge and Cd. In this embodiment, the channel layer 13 is made of IGZO material. The channel layer 13 can be amorphous, poly-crystal or crystal. In this embodiment, the channel layer 13 includes microcrystal structures.

The source electrode 14 and the drain electrode 15 are formed on an upper surface of the channel layer 13, and located at two opposite ends of the upper surface of the channel layer 13.

The gate insulating layer 16 is formed on an upper surface of the channel layer 13, and partly covers the source electrode 14 and the drain electrode 15. The gate insulating layer 16 is made of a material selected from SiOx, SiNx and SiONx, or insulating materials with a high dielectric constant such as Ta₂O₅ and HfO₂.

The gate electrode 17 is formed on an upper surface of the gate insulating layer 16 and located in a middle portion of the upper surface of the gate insulating layer 16. The gate electrode 17 is made of a material selected from Cu, Al, Ni, Mg, Cr, Mo, W and alloy thereof.

Since the organic air block layer 12 can prevent air from contacting the channel layer 13, the channel layer 13 of the thin film transistor 10 is not easy to be damaged by oxygen content in outer environment. In addition, when the organic air block layer 12 is made of hydrophobes, the organic air block layer 12 can also prevent steam of outer environment from contacting the channel layer 13. Furthermore, because the organic air block layer 12 is formed by chemical vapor deposition or by solution processes, the channel layer 13 will not be damaged by plasma in plasma-enhanced chemical vapor deposition or sputtering. Therefore, affecting of plasma on the threshold voltage, current on-off ratio, sub-threshold of the thin film transistor is avoided, and a quality of the thin film transistor is increased.

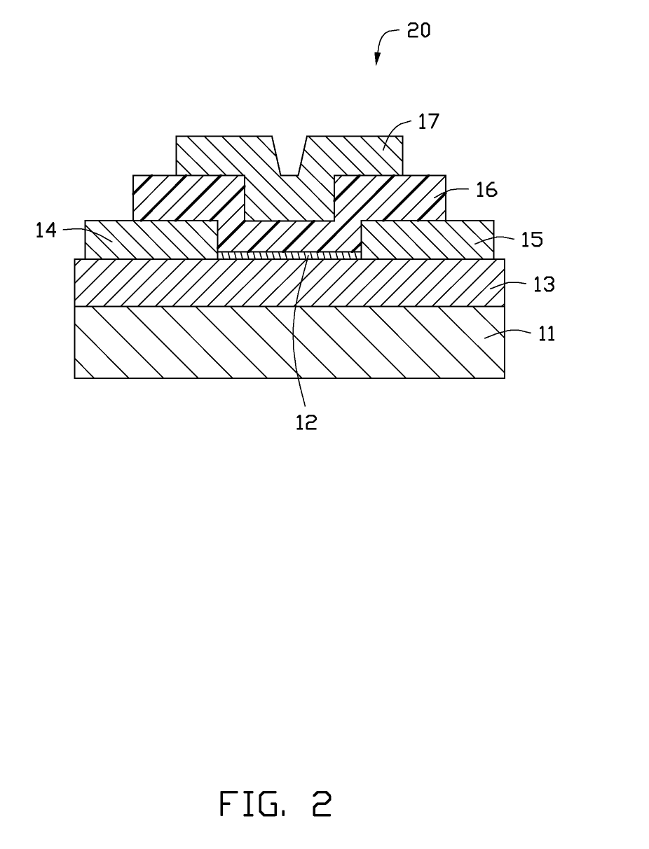

Referring to FIG. 2, a thin film transistor 20 in accordance with a second embodiment is provided. The thin film transistor 20 includes a substrate 11, an organic air block layer 12, a channel layer 13, a source electrode 14, a drain electrode 15, a gate insulating layer 16 and a gate electrode 17. The structure of the thin film transistor 20 is similar to that of the thin film transistor 10. Different from the first embodiment, the organic air block layer 12 is formed on an upper surface of the channel layer 13. Therefore, the organic air block layer 12 is located between the gate insulating layer 16 and the channel layer 13.

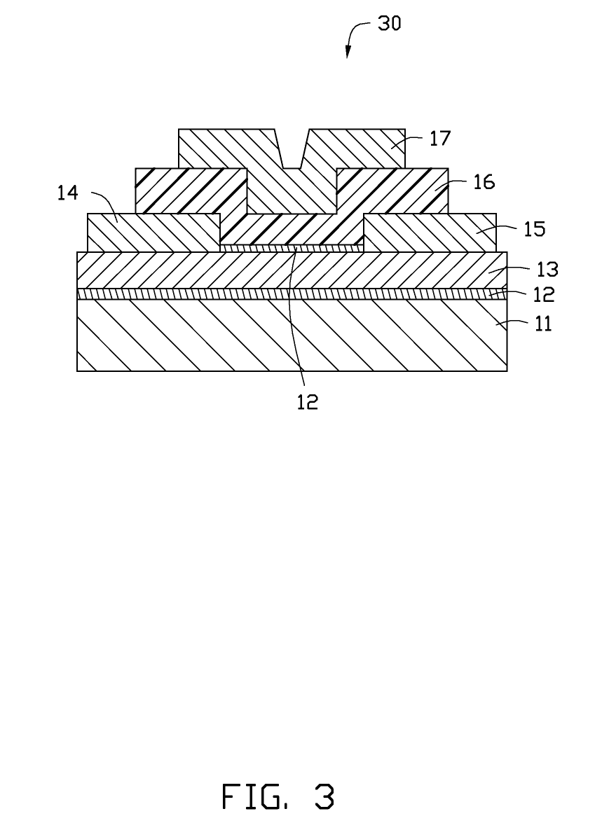

Referring to FIG. 3, a thin film transistor 30 in accordance with a third embodiment is provided. The thin film transistor 30 includes a substrate 11, two organic air block layers 12, a channel layer 13, a source electrode 14, a drain electrode 15, a gate insulating layer 16 and a gate electrode 17. The structure of the thin film transistor 30 is similar to that of the thin film transistor 10. Different from the first embodiment, one of the organic air block layers 12 is located between the gate insulating layer 16 and the channel layer 13. Another of the organic air block layers 12 is located between the channel layer 13 and the substrate 11.

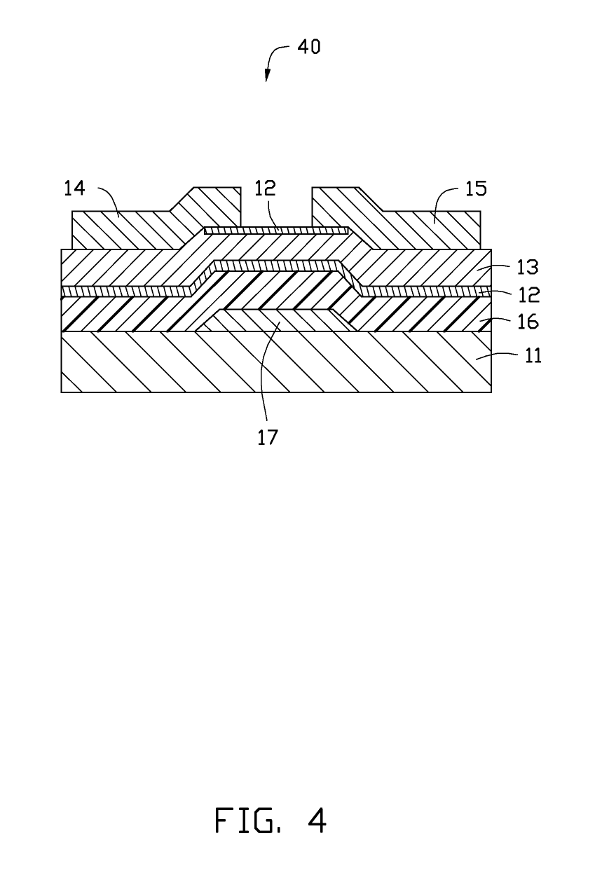

Referring to FIG. 4, a thin film transistor 40 in accordance with a fourth embodiment is provided. The thin film transistor 40 includes a substrate 11, two organic air block layers 12, a channel layer 13, a source electrode 14, a drain electrode 15, a gate insulating layer 16 and a gate electrode 17. Different from embodiments described above, the thin film transistors 10, 20, 30 have top gate structures, and the thin film transistor 40 has a bottom gate structure. That is, the gate electrode 17 is formed on an upper surface of the substrate 11 and located in a middle portion of the upper surface of the substrate 11. The gate insulating layer 16 is formed on the upper surface of the substrate 11 and covers the gate electrode 17. A first organic air block layer 12 is formed on an upper surface of the gate insulating electrode. The channel layer 13 is formed on an upper surface of that organic air block layers 12. A second organic air block layers 12 is formed on an upper surface of the channel layer 13 and located in a middle portion of the upper surface of the channel layer 13. The source electrode 14 and the drain electrode 15 are located at two lateral sides of the upper surface of the channel layer 13. In this embodiment, the source electrode 14 and the drain electrode 15 partly cover on the second organic air block layers 12.

In alternative embodiments, the thin film transistor can further include an inorganic air block layer.

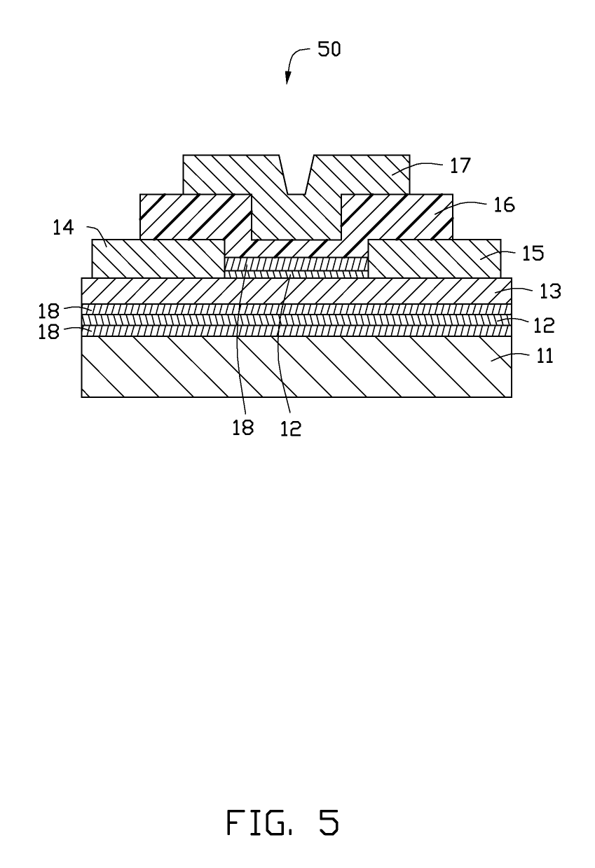

Referring to FIG. 5, a thin film transistor 50 having inorganic air block layer 18 is provided. The thin film transistor 50 is similar to the thin film transistor 30 in the third embodiment. Different from the third embodiment, the thin film transistor 50 includes three inorganic air block layer 18. A first inorganic air block layer 18 is located between the substrate 11 and the first organic air block layer 12. A second inorganic air block layer 18 is located between the first organic air block layer 12 and the channel layer 13. A third inorganic air block layer 18 is located between the source electrode 14 and the drain electrode 15 and covers on the second organic air block layer 12.

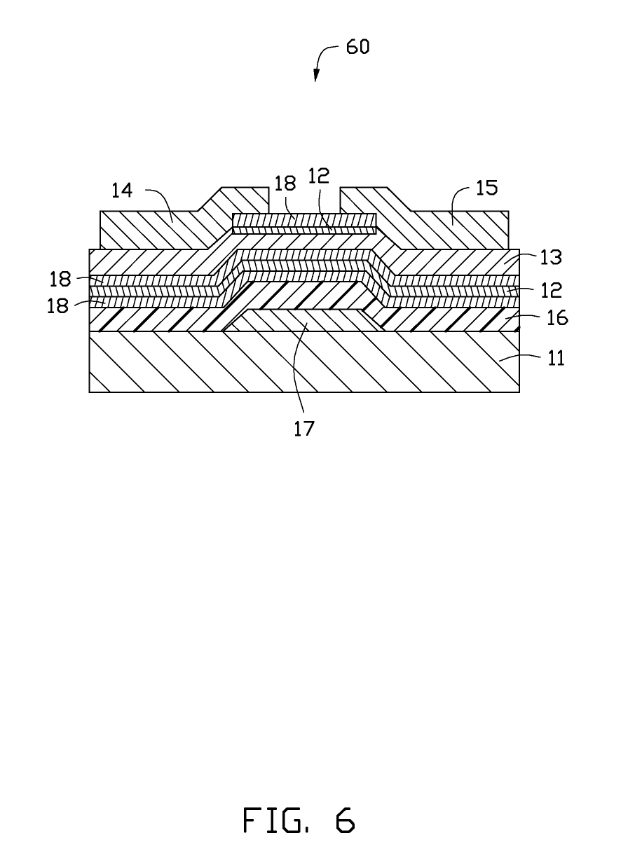

Referring to FIG. 6, a thin film transistor 60 having inorganic air block layer 18 is provided. The thin film transistor 60 is similar to the thin film transistor 40 in the fourth embodiment. Different from the third embodiment, the thin film transistor 60 includes three inorganic air block layer 18. A first inorganic air block layer 18 is located between the gate insulating layer 16 and the first organic air block layer 12. A second inorganic air block layer 18 is located between the first organic air block layer 12 and the channel layer 13. A third inorganic air block layer 18 is located on the second organic air block layer 12 and partly covered by the source electrode 14 and the drain electrode 15.

The inorganic air block layers 18 are made of oxides, nitrides or nitrogen oxides. In this embodiment, the inorganic air block layers 18 are made of a material selected from SiOₓ, SiNₓ, SiON and AlOₓ.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A thin film transistor, comprising:
a substrate;
a channel layer formed on an upper surface of the substrate;
a source electrode and a drain electrode formed on an upper surface of the channel layer and located at two opposite ends of the upper surface of the channel layer;
a gate insulating layer located in a middle portion of the upper surface of the channel layer; and
a gate electrode located on an upper surface of the gate insulating layer;
wherein a first organic air block layer is formed between the substrate and the channel layer.

2. The thin film transistor of claim 1, wherein the first organic air block layer is made of hydrophobes.

3. The thin film transistor of claim 2, wherein the first organic air block layer is made of a material selected from Hexamethyldisiloxane, Hexamethyldisilazane, Polymethyl Methacrylate, Epoxy, Polycarbonate and Plastic.

4. The thin film transistor of claim 2, wherein the first organic air block layer has a refractive index not less than 1.2.

5. The thin film transistor of claim 1, further comprising a second organic air block layer formed between the channel layer and the gate insulating layer.

6. The thin film transistor of claim 5, further comprising three inorganic air block layers respectively designated as a first inorganic air block layer, a second inorganic air block layer and a third inorganic air block layer, the first inorganic air block layer being located between the substrate and the first organic air block layer, the second inorganic air block layer being located between the first organic air block layer and the channel layer, the third inorganic air block layer being located between the source electrode and the drain electrode, the third inorganic air block layer covering on the second organic air block layer.

7. The thin film transistor of claim 6, wherein the three inorganic air block layers are all made of oxides, nitrides or nitrogen oxides.

8. The thin film transistor of claim 7, wherein the inorganic air block layers are made of a material selected from SiOₓ, SiNₓ, SiON and AlOₓ.

9. The thin film transistor of claim 1, wherein the channel layer is made of metallic oxide semiconductor, which comprises at least one of In, Ga, Zn, Sn, Al, Pb, Mo, Mn, Mg, Ge and Cd.

10. The thin film transistor of claim 1, wherein the channel layer can be amorphous, poly-crystal or crystal.

11. A thin film transistor, comprising:
a substrate;
a gate electrode formed on an upper surface of the substrate and located in a middle portion of the upper surface of the substrate;
a gate insulating layer formed on an upper surface of the substrate and covering the gate electrode;
a channel layer formed on an upper surface of the gate insulating layer; and
a source electrode and a drain electrode formed on an upper surface of the channel layer and located at two opposite ends of the upper surface of the channel layer; wherein
a first organic air block layer is formed between the gate insulating layer and the channel layer.

12. The thin film transistor of claim 11, wherein the first organic air block layer is made of hydrophobes.

13. The thin film transistor of claim 12, wherein the first organic air block layer is made of a material selected from Hexamethyldisiloxane, Hexamethyldisilazane, Polymethyl Methacrylate, Epoxy, Polycarbonate and Plastic.

14. The thin film transistor of claim 12, wherein the first organic air block layer has a refractive index not less than 1.2.

15. The thin film transistor of claim 11, further comprising a second organic air block layer formed on the upper surface of the channel layer.

16. The thin film transistor of claim 15, further comprising three inorganic air block layers respectively designated as a first inorganic air block layer, a second inorganic air block layer and a third inorganic air block layer, the first inorganic air block layer being located between the substrate and the first organic air block layer, the second inorganic air block layer being located between the first organic air block layer and the channel layer, the third inorganic air block layer being located between the source electrode and the drain electrode, the third inorganic air block layer covering on the second organic air block layer.

17. The thin film transistor of claim 16, wherein the three inorganic air block layers are all made of oxides, nitrides or nitrogen oxides.

18. The thin film transistor of claim 17, wherein the inorganic air block layers are made of a material selected from SiOₓ, SiNₓ, SiON and AlOₓ.

19. The thin film transistor of claim 11, wherein the channel layer is made of metallic oxide semiconductor, which comprises at least one of In, Ga, Zn, Sn, Al, Pb, Mo, Mn, Mg, Ge and Cd.

20. The thin film transistor of claim 11, wherein the channel layer can be amorphous, poly-crystal or crystal.
